(19) United States
(12) Patent Application Publication
(10) Pub. No.: US 2024/0266152 A1
(43) Pub. Date: Aug. 8, 2024

(54) PLASMA UNIFORMITY CONTROL SYSTEM AND METHODS

(71) Applicant: Applied Materials, Inc., Santa Clara, CA (US)

(72) Inventors: Michael Andrew STEARNS, San Jose, CA (US); Alok RANJAN, Santa Clara, CA (US); Kartik RAMASWAMY, San Jose, CA (US); Peng TIAN, Santa Clara, CA (US); Timothy Joseph FRANKLIN, Campbell, CA (US); Chris BLANK, Santa Clara, CA (US); Carlaton WONG, Sunnyvale, CA (US)

(21) Appl. No.: 18/107,487

(22) Filed: Feb. 8, 2023

(51) Int. Cl. H01J 37/32; H01F 27/28; H01L 21/3065

(52) U.S. Cl. CPC H01J 37/3266; H01F 27/28; H01J 37/3211; H01L 21/3065; H01J 2237/0264; H01J 2237/3341; H01J 2237/3343

(57) ABSTRACT

Embodiments of the present disclosure include an apparatus and methods for the plasma processing of a substrate. Some embodiments are directed to a plasma processing chamber. The plasma processing chamber generally includes a planar coil region comprising a concentric coil region comprising a first concentric coil and a second concentric coil, and a power supply circuit coupled to the first concentric coil and the second concentric coil. The first concentric coil may include a first coil with a diameter measured in a direction parallel to a first plane that is smaller than the diameter of a second coil included in the second concentric coil. The power supply circuit may be configured to bias the first concentric coil and the second concentric coil to adjust a generated magnetic field in a region of control of a plasma in the plasma processing chamber to control a plasma density of the plasma.

### BACKGROUND

### Field

Embodiments of the present disclosure generally relate to a system used in semiconductor device manufacturing. More specifically, embodiments of the present disclosure relate to a plasma processing system used to plasma process a substrate and methods of using the same.

### Description of the Related Art

Reliably producing high aspect ratio features is one of the key technology challenges for the next generation of semiconductor devices. One method of forming high aspect ratio features uses a plasma-assisted etching process to bombard a material formed on a surface of a substrate through openings formed in a patterned mask layer formed on the substrate surface.

With technology nodes advancing towards two nanometers (nm), the fabrication of smaller features with larger aspect ratios requires atomic precision for plasma processing. For etching processes where the plasma ions play a major role, ion energy control is always challenging the development of reliable and repeatable device formation processes in the semiconductor equipment industry. In a typical plasma-assisted etching process, the substrate is positioned on a substrate support disposed in a processing chamber, a plasma is formed over the substrate by use of a radio frequency (RF) generator that is coupled to an electrode disposed on or within the plasma processing chamber, and ions are accelerated from the plasma towards the substrate across a plasma sheath. Additionally, RF substrate biasing methods, which require the use of a separate RF biasing source in addition to the RF generator that is used to initiate and maintain the plasma in the processing chamber, have been unable to desirably control the plasma sheath properties to achieve desirable plasma processing results that will allow the formation of these smaller device feature sizes.

However, non-uniformities in the plasma density and/or in the shape of the plasma sheath can occur, due to the variations in the electrical characteristics of and/or spatial arrangement of the processing components disposed within a processing region of a plasma processing chamber. One common plasma density variation is created within conventional inductively coupled plasma sources that include a coil that is positioned over the processing region of a plasma chamber due to structural, alignment, and/or orientation variations found of conventional coil designs that often create plasma non-uniformity and both local and global tilt variations in the plasma processing results achieved on substrates processed in a plasma processing chamber. The variation in plasma uniformity and tilt of the sheath created by a coil will cause undesirable processing results in etched features formed across the surface of the substrate. Excessive variation in plasma non-uniformity will adversely affect the process results and reduce device yield. Such non-uniformities are often particularly pronounced near or between the center and edge of the substrate.

Accordingly, there is a need in the art to control and/or minimize the adverse effects of plasma non-uniformity inside the plasma chamber. There is also a need for a system, device(s), and methods that solve the problems described above.

### SUMMARY

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

Embodiments provided herein generally include apparatus, plasma processing systems, and methods for generation of a waveform for plasma processing of a substrate in a processing chamber.

Embodiments of the present disclosure provide a plasma processing chamber. The plasma processing chamber generally a concentric coil region comprising a first concentric coil, a second concentric coil, and a third concentric coil, wherein the first concentric coil comprises a first coil that has a first diameter that is measured in a direction parallel to a first plane, the second concentric coil comprises a second coil that has a second diameter that is measured in a direction parallel to the first plane, the third concentric coil comprises a third coil that has a third radius that is measured in a direction parallel to the first plane, and the second radius is smaller than the third radius, and the first radius is smaller than the second radius. The plasma processing chamber also generally includes a power supply circuit coupled to the first concentric coil, the second concentric coil, and the third concentric coil, wherein the power supply circuit is configured to bias the first concentric coil, the second concentric coil, and the third concentric coil to adjust a generated magnetic field in a region of control of a plasma in the plasma processing chamber to control a plasma density of the plasma, and wherein at least one of the first concentric coil, the second concentric coil, and the third concentric coil is biased oppositely of the other concentric coils.

Embodiments of the present disclosure provide a method of processing a substrate. The method of processing a substrate generally includes performing a processing sequence on the substrate disposed within a processing region of a plasma processing chamber. The processing sequence generally includes biasing, with a power supply circuit, at least three of a plurality of concentric coils to adjust a generated magnetic field in a region of control of a plasma in the plasma processing chamber to control a plasma density of the plasma by changing an absolute magnitude of a current applied to the at least three of the plurality of concentric coils to change a radial flux in the region of control. Biasing the at least three of the plurality of concentric coils generally includes delivering a first bias signal to a coil of a first concentric coil of the plurality of concentric coils; delivering a second bias signal to a coil of a second concentric coil of the plurality of concentric coils; and delivering a third bias signal to a coil of a third concentric coil of the plurality of concentric coils.

Embodiments of the present disclosure provide a method of processing a substrate. The method of processing a substrate generally includes performing a processing sequence on the substrate disposed within a processing region of a plasma processing chamber. The processing sequence generally includes biasing, with a power supply circuit, at least two of a plurality of concentrically aligned coils to adjust a generated magnetic field in a region of control of a plasma in the plasma processing chamber to control a plasma density of the plasma by changing an absolute magnitude of a current applied to the at least two of the plurality of concentrically aligned coils to change a radial flux in the region of control. Biasing the at least two of the plurality of concentrically aligned coils comprises: delivering a first bias signal to a coil of a first concentric coil of the plurality of concentrically aligned coils at a first time; and delivering a second bias signal to a coil of a second concentric coil of the plurality of concentrically aligned coils at a second time.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope and may admit to other equally effective embodiments.

FIG. 1 is a simplified schematic side cross-sectional view of a plasma processing system that can be configured to practice the methods set forth herein, in accordance with certain embodiments of the present disclosure.

FIG. 2 is a schematic side cross-sectional isometric view of a field generation system, according to one or more embodiments, in accordance with certain embodiments of the present disclosure.

FIG. 3 is a schematic bottom view of a field generation system, in accordance with certain embodiments of the present disclosure.

FIG. 4 is a schematic view of a power supply circuit assembly of a power delivery system of a plasma processing system, in accordance with certain embodiments of the present disclosure.

FIG. 5 is a flow diagram depicting a method for performing a plasma processing sequence, according to one or more of the embodiments described herein.

FIG. 6 is a schematic view of a coil region, a region of control, and a plasma density during a plasma processing sequence, in accordance with certain embodiments of the present disclosure.

FIG. 7 is a schematic view of a coil region, a region of control, and a plasma density during a plasma processing sequence, in accordance with certain embodiments of the present disclosure.

FIG. 8 is a schematic view of a coil region, a region of control, and a plasma density during a plasma processing sequence, in accordance with certain embodiments of the present disclosure.

FIG. 9 is a schematic view of a coil region, a region of control, and a plasma density during a plasma processing sequence, in accordance with certain embodiments of the present disclosure.

To facilitate understanding, identical reference numerals have been used, where possible, to designate identical elements that are common to the figures. It is contemplated that elements and features of one implementation may be beneficially incorporated in other implementations without further recitation.

### DETAILED DESCRIPTION

In the following description, details are set forth by way of example to facilitate an understanding of the disclosed subject matter. It should be apparent to a person of ordinary skill in the field, however, that the disclosed implementations are exemplary and not exhaustive of all possible implementations. Thus, it should be understood that reference to the described examples is not intended to limit the scope of the disclosure. Any alterations and further modifications to the described devices, instruments, methods, and any further application of the principles of the present disclosure are fully contemplated as would normally occur to one skilled in the art to which the disclosure relates. In particular, it is fully contemplated that the features, components, and/or steps described with respect to one implementation may be combined with the features, components, and/or steps described with respect to other implementations of the present disclosure. As used herein, the term “about” may refer to a +/−10% variation from the nominal value. It is to be understood that such a variation can be included in any value provided herein.

Embodiments of the present disclosure generally relate to a system that can be used in a semiconductor device manufacturing process sequence. More specifically, embodiments provided herein generally include apparatus and methods for controlling the delivery and control of magnetic fields generated from a field generation system disposed within a plasma processing chamber. The apparatus and methods disclosed herein can be useful to at least minimize or eliminate the effects of plasma non-uniformity on a substrate. The plasma processing methods and apparatus described herein are configured to improve the control of various characteristics of the generated plasma and control an ion energy distribution (IED) of the plasma generated ions that interact with a surface of a substrate during plasma processing. The ability to control the magnetic fields generated from a field generation system during processing allows for an improved control of one or more characteristics of the generated plasma, such as plasma uniformity, plasma density and shape, local and global tilt, IED, electron energy distribution (EED), or other useful parameters. The improved control of the plasma is used to improve the plasma processing results performed in the plasma processing chamber, for example, forming desirable high-aspect ratio features in the surface of the substrate by a reactive ion etching (RIE) process. As a result, greater precision for plasma processing can be achieved, which is described herein in more detail.

Embodiments of the present disclosure provide an apparatus and method for controlling the fields generated by one or more coils in a field generation system of a plasma processing system in order to achieve greater precision during plasma processing.

### Plasma Processing System Example

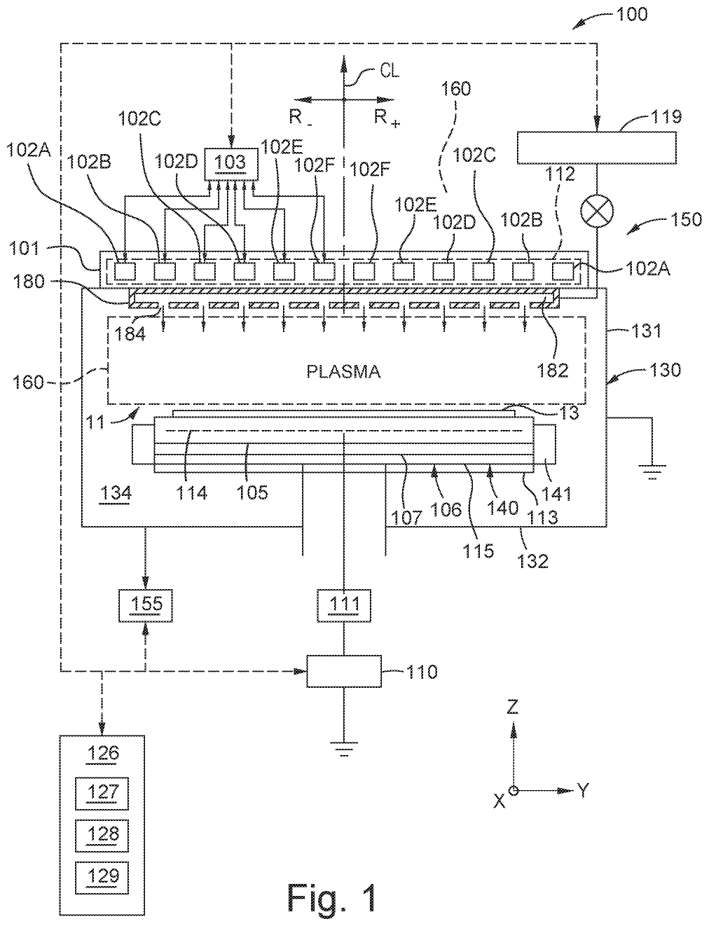

FIG. 1 is a simplified schematic of a plasma processing system 100 that can be configured to practice the methods set forth herein. In FIG. 1 and subsequent figures in the present disclosure, “CL” represents the center line of the plasma processing system 100, R− represents the negative radial direction, and R+ represents the positive radial direction. The plasma processing system 100 is adapted to process a substrate 13 disposed on a substrate support assembly 140 by generating a plasma 11 within the processing volume 134 of a plasma processing chamber 150. In some embodiments, the formed plasma 11 may form a region of control 160. The plasma processing system 100 is configured to form an inductively coupled plasma (ICP), where the plasma processing chamber 150 includes a field generation system 101 disposed over a portion of the processing volume 134 so that at least a portion of the field generation system 101 is facing a biasing electrode 114. The biasing electrode 114 is disposed within substrate support assembly 140 that is disposed within the processing volume 134. The biasing electrode 114 is also often referred to herein as a substrate support electrode, and may be coupled to a generator 110.

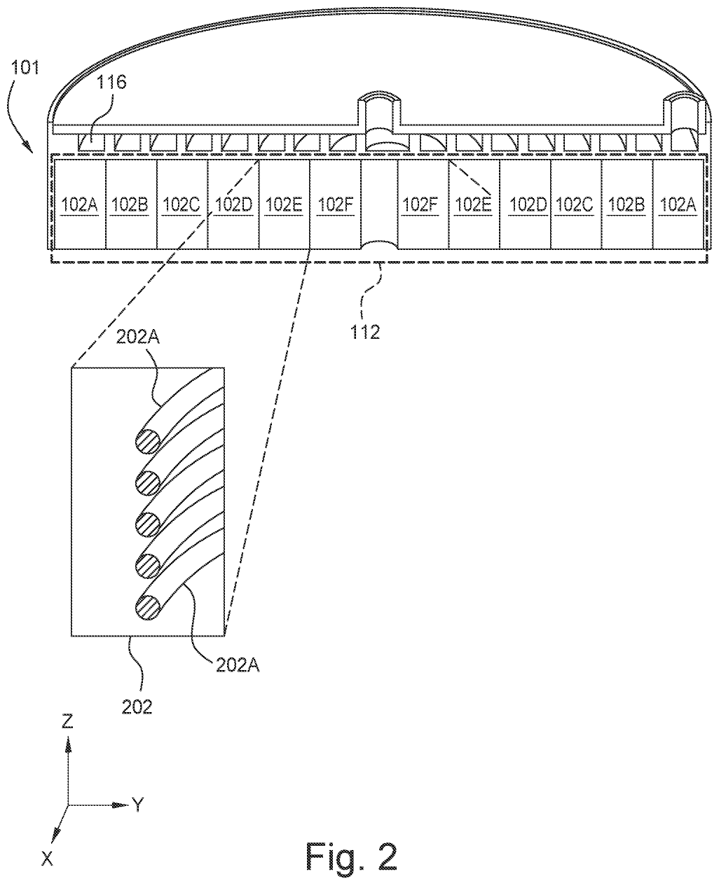

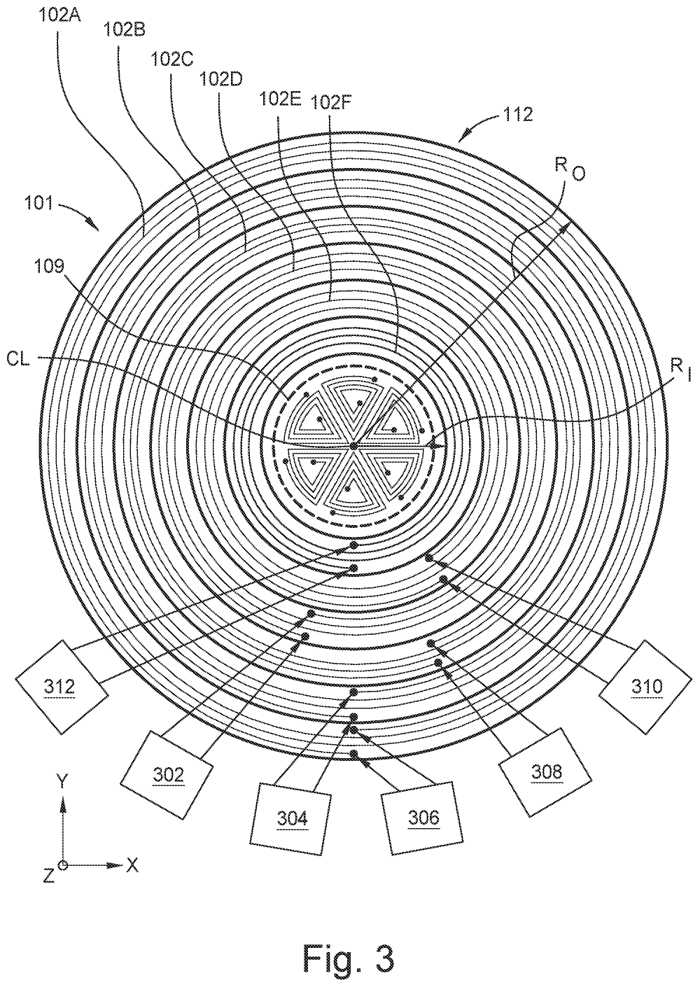

In some embodiments, the field generation system 101 includes one or more coils (e.g., concentric coils 102A, 102B, 102C, 102D, 102E, 102F) in a concentric coil region 112. The one or more concentric coils are wound in a circular orientation and may form a ring, with some concentric coils nested within other concentric coils, as illustrated in FIG. 3. At least one of the one or more concentric coils may be a solenoid type of coil. The one or more concentric coils may be disposed above the processing volume 134 in which the plasma 11 is formed, which is often referred to herein as a region of control 160. The concentric coils may be coils which include multiple coil layers that are aligned in a vertical direction (i.e., Z-direction), as illustrated in FIG. 2. Although six concentric coils are shown in the example of FIGS. 1 and 2, any number of concentric may be used. In some embodiments, the field generation system 101 is coupled to a power delivery system 103. The power delivery system 103 may include a power supply circuit assembly with a separate source driver for each concentric coil, such that each source driver being configured to bias (e.g., drive) the concentric coils. In other configurations, the power supply circuit assembly may include fewer source drivers than concentric coils, such that one source driver may be configured to bias multiple coils.

The plasma processing chamber 150 typically includes a chamber body 130 that includes one or more sidewalls 131 and a chamber base 132, which collectively, with a chamber lid 133, define the processing volume 134. The one or more sidewalls 131 and chamber base 132 generally include materials that are sized and shaped to form the structural support for the elements of the plasma processing chamber 150 and are configured to withstand the pressures and added energy applied to them while a plasma 11 is generated within a vacuum environment maintained in the processing volume 134 of the plasma processing chamber 150 during processing. In one example, the one or more sidewalls 131 and chamber base 132 are formed from a metal, such as aluminum, an aluminum alloy, or a stainless steel alloy.

In some embodiments, the field generation system 101 is coupled to or disposed over a showerhead 180. The showerhead 180 includes a gas plenum region 182 and a number of openings 184. The showerhead 180 is disposed through the chamber lid 133 and is used to deliver one or more processing gases through the openings 184 to the processing volume 134 from a processing gas source 119 that is in fluid communication therewith. The processing gases provided by the processing gas source 119 will include reactive etchant gases and/or inert gases. The pressure within the plasma processing chamber 150 may be controlled by use of a vacuum pump (not shown) and an amount of gas flow provided from the processing gas source 119. A substrate 13 is loaded into, and removed from, the processing volume 134 through an opening (not shown) in one of the one or more sidewalls 131, which is sealed with a slit valve (not shown) during plasma processing of the substrate 13. The showerhead 180 is comprised of materials with a low magnetic permeability, such that biasing the concentric coils in the field generation system 101 generates magnetic fields that can affect the plasma 11 in the region of control 160 of the processing volume 134. For example, the showerhead 180 may be a metallic plate, and may comprise aluminum, quartz or other materials with a low magnetic permeability.

In some embodiments, the generator 110 may be a pulsed voltage (PV) waveform generator, which is electrically coupled to the biasing electrode 114 through an RF filter 111 that is configured to prevent RF signals from making their way to the generator 110 during processing. The generator 110 may also be an RF source generator, which is electrically coupled to the biasing electrode 114 through an RF filter 111, and may deliver an RF signal configured to ignite and maintain a plasma (e.g., the plasma 11).

The substrate support assembly 140 can include a substrate support 105 (e.g., ESC substrate support) and one or more biasing electrodes, which are coupled to the generator 110. In some embodiments, the substrate support assembly 140 can additionally include a support structure 106 that includes a support base 107, which supports the substrate support 105, an insulator plate 115 and a ground plate 113 that is coupled to the chamber base 132. The support base is electrically isolated from the chamber base 132 by the insulator plate, and the ground plate is interposed between the insulator plate and the chamber base 132. A dielectric containing isolation ring 141 is typically positioned around the substrate support 105, the insulator plate and the ground plate. The substrate support 105 is thermally coupled to and disposed on the support base, which is configured to regulate the temperature of the substrate support 105 during processing.

Typically, the substrate support 105 is formed of a dielectric material, such as a bulk sintered ceramic material, such as a corrosion-resistant metal oxide or metal nitride material. In embodiments herein, the substrate support assembly 140 further includes the biasing electrode 114 embedded in the dielectric material thereof. In one configuration, the biasing electrode 114 is a chucking pole used to secure (e.g., chuck) the substrate 13 to the substrate supporting surface of the substrate support assembly 140 and to bias the substrate 13 with respect to the processing plasma 11 using one or more of the pulsed-voltage biasing schemes described herein. Typically, the bias electrode 114 is formed of one or more electrically conductive parts, such as one or more metal meshes, foils, plates, or combinations thereof. In some embodiments, the biasing electrode 114 is also electrically coupled to a clamping network that is configured to provide a chucking voltage thereto, such as static direct current (DC) voltage between about −5000 V and about +5000 V.

A system controller 126, also referred to herein as a plasma processing chamber controller, includes a central processing unit (CPU) 127, a memory 128, and support circuits 129. The system controller 126 is used to control the process sequences and methods used to process the substrate 13, including the substrate 13 processing methods described herein. The CPU 127 is a general-purpose computer processor configured for use in an industrial setting for controlling the plasma processing chamber and sub-processors related thereto. The memory 128 described herein, which is generally non-volatile memory, may include random access memory, read-only memory, floppy or hard disk drive, or other suitable forms of digital storage, local or remote. The support circuits 129 are conventionally coupled to the CPU 127 and comprise cache, clock circuits, input/output subsystems, power supplies, and the like, and combinations thereof. Software instructions (software program) and data can be coded and stored within the memory 128 for instructing a processor within the CPU 127. A software program (or computer instructions) readable by CPU 127 in the system controller 126 determines which tasks are performable by the components in the processing system 100. Typically, the software program, which is readable by CPU 127 in the system controller 126, includes code, which, when executed by the processor (CPU 127), performs tasks relating to the plasma processing methods described herein. The program may include instructions that are used to control the various hardware and electrical components within the plasma processing chamber 150 and processing system 100 to perform the various process tasks and various process sequences used to implement the methods described herein.

In one or more of the embodiments disclosed herein, the plasma processing chamber 150 includes a sensor assembly (not shown) that is positioned to measure characteristics of the PV waveform generated at the source generator 110 output and/or RF waveform generated by the power delivery system 103 output. The sensor assembly can include one or more electrical components that are configured to measure one or more electrical characteristics of a pulsed voltage waveform provided by the source generator 110, such as voltage, current and offset/phase, and send the one or more electrical characteristic data to the system controller 126. The sensor assembly can also include one or more electrical components that are configured to measure one or more electrical characteristics of the voltage, current, and/or phase of a direct current (DC) or alternating current (AC) waveform (e.g., sinusoidal waveform) provided to the concentric coils 102 provided from the power delivery system 103, and send the one or more electrical characteristic data to the system controller 126. The electrical characteristic data received by the system controller 126 from the source generator 110 can be used together to synchronize the delivery of other PV waveforms generated by the generator 110 and power delivery system 103, as is discussed further below.

While the disclosure provided herein, primarily discusses the use of the processing system 100 to perform a plasma-assisted etching processes, such as a reactive ion etch (RIE) plasma processing technique this configuration is not intended to limit the scope of disclosure provided herein. It should be noted that the embodiments described herein may be also be used with processing systems configured for use in other plasma-assisted processes, such as plasma-enhanced deposition processes, for example, plasma-enhanced chemical vapor deposition (PECVD) processes, plasma-enhanced physical vapor deposition (PEPVD) processes, plasma-enhanced atomic layer deposition (PEALD) processes, plasma treatment processing or plasma-based ion implant processing, for example, plasma doping (PLAD) processing.

### Field Generation System Example

FIG. 2 is a schematic side cross-sectional view of an example of a field generation system 101. As described above, the field generation system 101 includes a concentric coil region 112. In some embodiments, the field generation system 101 may include a number of coolant channels 116 disposed above the concentric coil region 112 that are configured to cool the coils in the concentric coil region 118. The coolant channels 116 can be formed in a plate 117 that includes a high magnetic permeability material, such as an iron containing material, cobalt containing material, steel, ferrite or other similar material. The concentric coil region 112 may include one or more concentric coils (e.g., concentric coils 102A, 102B, 102C, 102D, 102E, 102F). Each of the one or more concentric coils (except the outer coil) may be nested within another of the one or more concentric coils, as illustrated in FIGS. 2 and 3. The one or more concentric coils within the concentric coil region 112 may each comprise a coil 202A that is wound to form a plurality coil layers that aligned in a vertical direction, such as the multi-layer concentric coil 202 illustrated in FIG. 2, which is aligned in the Z-direction.

The number of wound layers utilized in each coil region 112 in the field generation system 101 may be adjusted in order to produce the desired magnetic field, which will include radial and azimuthal field components. As stated above, the one or more concentric coils are circular and may each form rings, as illustrated in FIG. 3. For example, coil 102A may at least partially surround coil 102B, coil 102B may at least partially surround coil 102C, and so on, as illustrated in FIG. 3. Although six concentric coils are shown in the example of FIG. 2, any number of concentric coils may be used.

FIG. 3 is a schematic bottom view of the field generation system 101 illustrated in FIGS. 1 and 2. In the example of FIG. 3, the concentric coil region 112 includes six concentric coils (e.g., concentric coils 102A, 102B, 102C, 102D, 102E, 102F). As stated above with respect to FIG. 2, the concentric coils may each comprise a coil that is wound to form multiple coil 202A layers. For schematic representation and ease of illustration purposes, the coils illustrated within the concentric coils 102A-102F are shown as being wound such that they have a planar orientation (e.g., X-Y plane). However, as noted above and below, it is desirable for the concentric coils 102A-102F to be wound such that the coils have a spiral or helical orientation that is primarily and substantially aligned about a central axis CL that is aligned in the vertical direction (e.g., Z-direction).

In some embodiments, the concentric coil region 112 has an inner radius R_{I} and an outer radius R_{O}. The inner radius R_{I} of the concentric coil region 112 is defined by the inner radius of an innermost concentric coil, such as concentric coil 102F in FIG. 3, and the outer radius R_{O} is defined by the outer radius of the outermost concentric coil, such as concentric coil 102A in FIG. 3. The inner radius R_{I} of the concentric coil region 112 can be between about 40 millimeters (mm) and about 100 mm in size. In one example, the inner radius R_{I} of the concentric coil region 112 is about 50 mm in size, while the outer radius R_{O} of the concentric coil region 112 is equal to or greater than the radius of the outer edge of the substrate 13, such as, for example, greater than or equal to 300 mm or 450 mm. In some embodiments, the outer radius R_{O} of the concentric coil region 112 can be less than the radius of the outer edge of the substrate 13, such as, for example, less than 300 mm. In some embodiments, the inner radius R_{I} to outer radius R_{O} ratio (i.e., R_{I}/R_{O}) of the concentric coil region 112 is between about 0.8 and about 0.4, such as between about 0.1 and about 0.35.

In some embodiments, each of the coils in the concentric coil region 112 may be coupled to a source driver (e.g., source drivers 302, 304, 306, 308, 310, 312), which are included in a power supply circuit assembly of the power delivery system 103. Each source driver may be configured to selectively bias adjacent concentric coils in the same or in opposing directions (e.g., positive and negative directions).

In some embodiments, the field generation system 101 may include a central region 109. The central region 109 may include additional coils (e.g., planar coils) or an electrode configured to at least minimize or eliminate the effects of plasma non-uniformity on a substrate 13 near the center of the processing chamber 150. In one example, as shown in FIG. 3, the central region 109 includes a plurality of planar coils that are each positioned in planar coil sectors or regions (e.g., six coil regions are shown) that each include a coil that is primarily wound in a direction that is parallel to the horizontal plane (i.e., X-Y plane).

### Power Delivery System Example

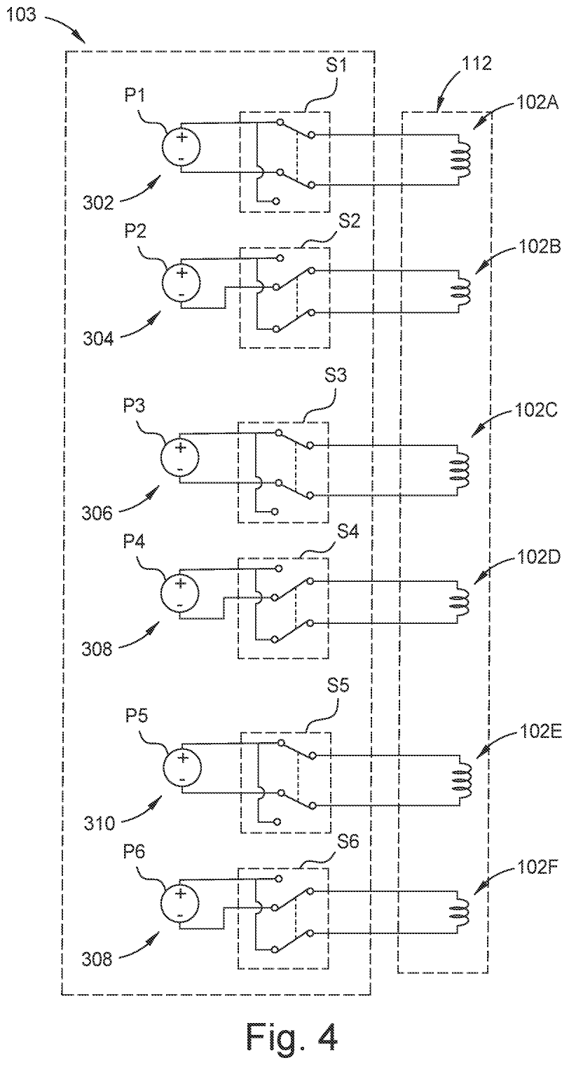

FIG. 4 is a schematic view of a power supply circuit assembly of a power delivery system 103 of a plasma processing system 100, in accordance with certain embodiments of the present disclosure. The power delivery system 103 may include a power supply circuit. The power supply circuit may be associated with the concentric coil region 112.

The power supply circuit may include a number of drivers (e.g., source drivers 302, 304, 306, 308, 310, 312), each source driver being configured to bias one or more coils (e.g., concentric coils 102A, 102B, 102C, 102D, 102E, 102F), which are wound in similar spiral or helical directions, in opposite directions (e.g., positive and negative current directions). In other words, biasing adjacent concentric coils in opposite directions may involve reversing the direction of the current flowing through the coils as desired. Each source driver may include a power supply (e.g., power supply P1, P2, P3, P4, P5, P6) coupled to a switch (e.g., switch S1, S2, S3, S4, S5, S6). The switches may be double throw switches or double pulse switches, as illustrated in the example of FIG. 4. In the position illustrated in the example of FIG. 4, the source drivers 302, 306, and 310 are configured to bias the similarly wound concentric coils 102A, 102C, and 102E in the concentric coil region 112 in a positive direction, while source drivers 304, 308, and 312 are configured to bias the similarly wound concentric coils 102B, 102D, and 102F in the concentric coil region 112 in a negative direction. When the switches S1, S3, and S5 are flipped from the positions illustrated in FIG. 4, the source drivers are configured to bias the coils in the concentric coil region 112 in a negative direction, and switches S2, S4, and S6 are flipped from the positions illustrated in FIG. 4 and the source drivers are configured to bias the coils in the concentric coil region 112 in a positive direction. In other words, flipping the switch of the drivers causes the current to flow in the opposite direction. The source drivers coupled to the concentric coils in the concentric coil region 112 are configured to bias adjacent concentric coils in opposite directions.

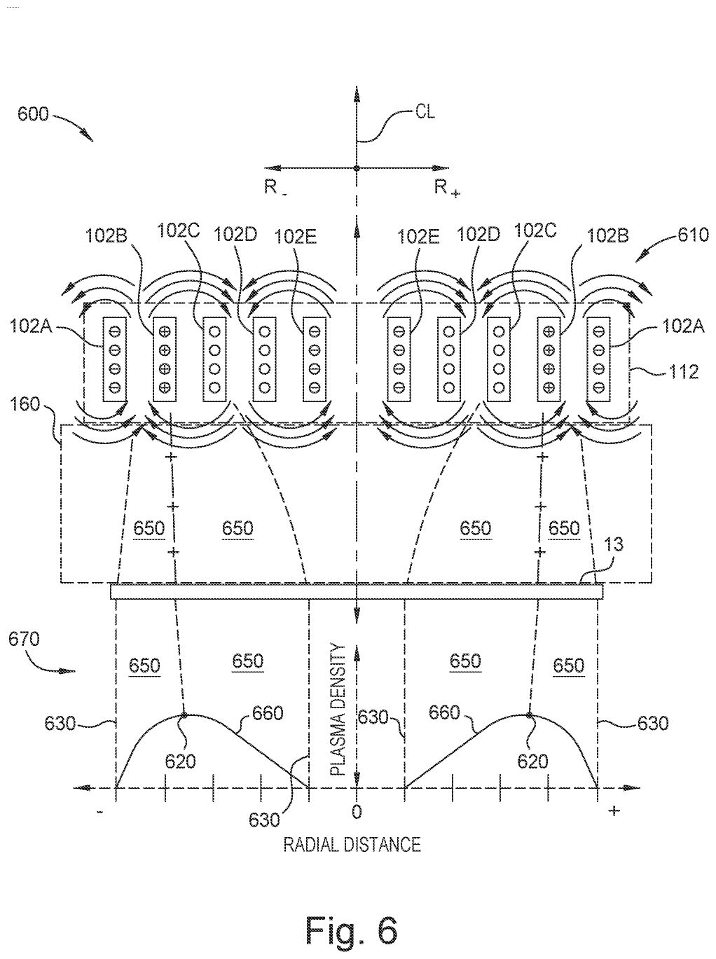

In some embodiments, the concentric coils in the concentric coil region 112 may be biased in a variety of ways to achieve preferred plasma uniformity, plasma density, and tilt control of the generated plasma 11. The plasma density and the shape of the plasma density on the substrate 13 may be manipulated by changing the intensity of the magnetic field formed by each of the concentric coils 102 in the concentric coil region 112 and the state of the coils in the concentric coil region 112 (e.g., which coils are in the off position, being biased in a positive direction, or being biased in a negative direction). For example, the peak or max plasma intensity on the substrate 13 (e.g., points 620, 720, 820, and 940 illustrated in FIGS. 6-9) that occurs as a result of the generated magnetic field created by powering one or more concentric coils is influenced and/or adjusted. The one or more source drivers coupled to the concentric coils in the concentric coil region 112 may be configured to bias (e.g., drive) the concentric coils in the concentric coil region 112 to affect the plasma 11 in the region of control 160 of the plasma processing chamber 150 (e.g., manipulate the generated magnetic field) by changing an absolute magnitude of the current applied to the concentric coils to change the generated radial magnetic flux in the region of control 160 of the plasma processing chamber 150, as is discussed further below. Changing the radial magnetic flux in the region of control 160 varies the magnetic field and thus the plasma density in the region of control 160.

The source drivers coupled to the concentric coils in the concentric coil region 112 may be configured to drive coils in the concentric coil region 112 with a continuous direct current (DC). For example, the source drivers may provide a continuous direct current to drive the coils in the concentric coil region 112. However, in some embodiments, it may be desirable for the source drivers to apply an AC signal to the concentric coils in the concentric coil region 112 at a frequency of about 10 hertz (Hz) or less, such as between one and two hertz (Hz).

### Processing Sequence Example

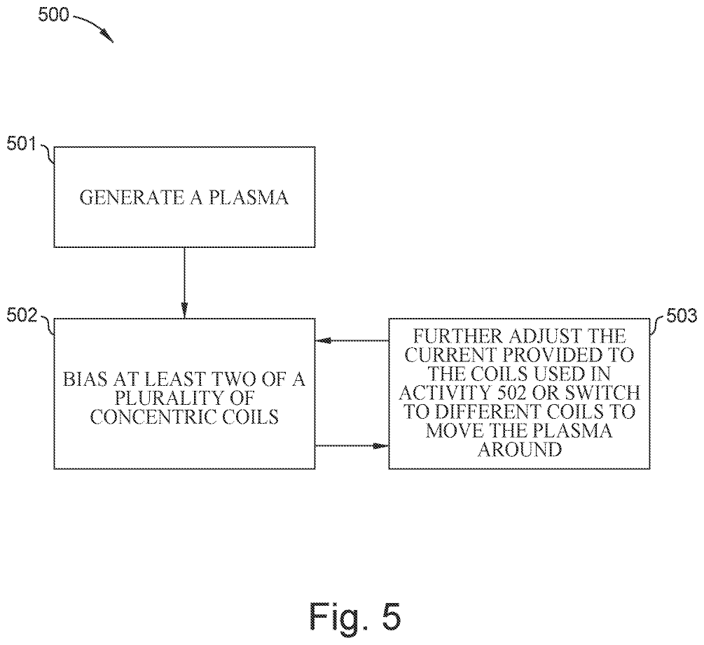

FIG. 5 is a flow diagram depicting a method 500 for performing a processing sequence, such as performing a processing sequence on a substrate 13 disposed within a processing volume 134 of a plasma processing chamber 150. The processing volume 134 may also be referred to as a processing region. FIGS. 6, 7, 8, and 9 illustrate example schematic views of a coil region (e.g., concentric coil region 112), a region of control 160, and a plasma density (shown in portions 670, 770, 870, and 970) during one or more of the activities illustrated in FIG. 5. Therefore, FIG. 5 and FIGS. 6-9 are herein described together for clarity. In addition, CL represents the center line in FIGS. 6-9, and the representation on the left side of the CL is mirrored on the right side of the CL.

The method 500 will include a plurality of activities used to perform a plasma processing activities on a substrate.

In activity 501, a plasma 11 is formed within the processing volume 134. In some embodiments, the plasma 11 is formed by the delivery of sufficient power to one or more of the concentric coils 102, or by use of an auxiliary source that is configured to generate the plasma 11 in the processing volume 134. In one example, the auxiliary source includes a capacitively coupled plasma (CCP) source electrode (e.g., support base 107 in FIG. 1) that is biased by a radio frequency (RF) source that provides an RF signal from an RF waveform generator. In some embodiments, the RF signal used to generate the plasma has a frequency that is greater than 400 kHz, such as a frequency of about 1 MHz or more, such as about 13.56 MHz or more, about 40 MHz or more, or, for example, between about 2 MHz and about 200 MHz.

Next at activity 502, a power supply circuit, which includes one or more of the source drivers 302, 304, 306, 308, 310, 312, biases at least two of a plurality of concentric coils (e.g., two or more concentric coils 102A, 102B, 102C, 102D, 102E) within the concentric coil region 112 to form a generated magnetic field in the region of control 160 of the plasma processing chamber 150 to control at least one characteristic of the formed plasma 11, such as a plasma density. The plasma 11 is controlled by delivering, or delivering and changing, an absolute magnitude of a current applied to the coil(s) within at least two of the plurality of concentric coils (e.g., two or more concentric coils 102A, 102B, 102C, 102D, 102E) to provide and/or change a radial flux in the region of control 160. In some embodiments, the coils within the concentric coils may be biased simultaneously, or even sequentially. Delivering and changing the radial flux and azimuthal flux in the region of control 160 causes the magnetic field and the plasma density in the region of control 160 to be altered. For example, the peak or max plasma intensity formed over the substrate 13 (e.g., points 620, 720, 820, and 940) is a result of the generated magnetic field generated by the biasing of the two or more concentric coils. The region of the region of control 160 where the plasma intensity over the substrate 13 (e.g., lines 630, 730, 830, and 930) is at a minimum, as a result of the concentric coil structure and magnetic field generated therefrom can also be adjusted. By manipulating the generated magnetic field and resultant maximum and minimum plasma intensities, the radial position and size of the plasma 11 within the region of control 160, as well as the resultant plasma density and shape, can be changed, manipulated and controlled. The manipulation of the position, radial plasma density profile and size of the plasma within the region of control 160 can be used as a plasma control and confinement technique.

Next at activity 503, a characteristic of the plasma 11 is optionally further adjusted in an effort to adjust the plasma uniformity (e.g., plasma intensity, shape, and/or position) and plasma tilt. Embodiments of the present disclosure enable the manipulation of the plasma uniformity (e.g., plasma intensity, shape, and/or position) and tilt of the plasma 11 over the substrate 13 by changing the intensity of the magnetic field formed by the coils in the concentric coil region 112 and/or the state of the coils in the concentric coil region 112 (e.g., which coils are in the off position, being biased in a positive direction, and being biased in a negative direction). For example, the intensity, position, and shape of the plasma density (e.g., curves 660, 760, 860, 960 shown in FIG. 6-9) is dependent upon both the intensity of the magnetic field formed by the coils in the concentric coil region 112, as well as the state of the coils in the concentric coil region 112. The various states of the coils can include one or more of the coils remaining unbiased, one or more coils being biased in a positive direction, and one or more coils being biased in a negative direction. FIGS. 6, 7, 8, and 9 illustrate examples of manipulating plasma uniformity by adjusting the intensity of the magnetic field formed by the concentric coils 102 in the concentric coil region 112 and/or the state of the coils in the concentric coil region 112.

In some embodiments, one or more concentric coils 102 within the concentric coil region 112 may be unbiased (e.g., “off position” (e.g., concentric coils 102C, 102D)), some coils may be biased in a positive direction (e.g., concentric coils 102B), and some coils may be biased in a negative direction (e.g., concentric coils 102A, 102E), as illustrated in FIG. 6. The interactions between the coils biased in a positive direction and the coils biased in a negative direction generate a magnetic field with magnetic field lines 610 within the region of control 160 (above the substrate 13). The portion 670 of FIG. 6 depicts a graph with a curve 660 illustrating the plasma intensity in the region of control 650 (in the radial direction) across the substrate 13 formed as a result of the magnetic field generated by the concentric coil region 112. Lines 630 on the curve 660 represent the portion of the graph where the plasma intensity on the substrate 13, as a result of the formed null regions within the generated magnetic field, is at a minimum or is effectively zero. The point 620 on the curve 660 represents the peak or max plasma intensity over the substrate 13 as a result of the generated magnetic field. The magnitude and shape of the curve 660 (the intensity and shape of the plasma density on the substrate 13) at each radial position is dependent upon both the magnitude or intensity of the magnetic field formed by the coils in the concentric coil region 112 at each radial position, which is affected by the state of the coils in the concentric coil region 112 (e.g., which coils are in the off position, being biased in a positive direction, and being biased in a negative direction).

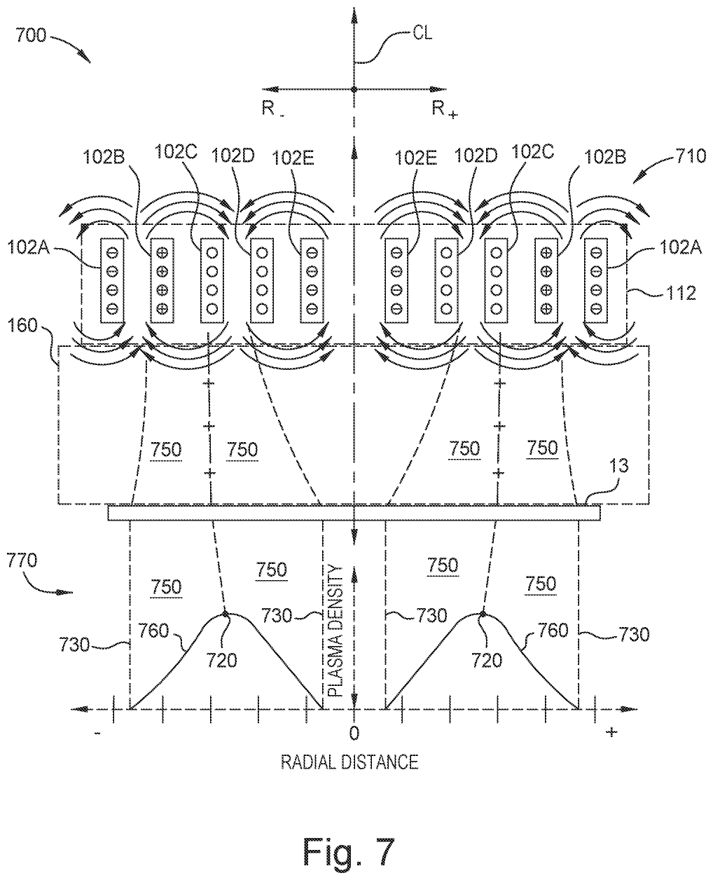

FIG. 7 illustrates an example in which the intensity of the magnetic field generated by the same coils utilized in FIG. 6 is greater than the intensity of the magnetic field illustrated in FIG. 6, as a result of supplying more electrical power (through the power supply circuit) to some of the coils in the concentric coil region 112. For example, the bias between the coils biased in a positive direction (e.g., concentric coil 102B), and the coils biased in a negative direction (e.g., concentric coils 102A) illustrated in FIG. 7 may be increased when compared to the example illustrated in FIG. 6. As a result, the peak or max plasma intensity over the substrate 13 (represented by point 720 on the curve 760) is shifted further towards the center of the substrate 13, and the curve 760 (e.g., the width of the curve between the lines 730) is also shifted further towards the center of the substrate 13 as a result of the increased intensity of the magnetic field. As similarly discussed in relation to FIG. 6, the interactions between the coils biased in a positive direction and the coils biased in a negative direction generate a magnetic field with magnetic field lines 710 in the region of control 160 (above the substrate 13). The portion 770 of FIG. 7 depicts a graph with a curve 760 illustrating the plasma intensity in the region of control 750 (in the radial direction) across the substrate 13 formed as a result of the magnetic field generated by the concentric coil region 112. Lines 730 on the curve 760 represent the portion of the graph where the plasma intensity over the substrate 13, as a result of the formed null regions within the generated magnetic field, is at a minimum or is effectively zero. The point 720 on the curve 760 represents the peak or max plasma intensity over the substrate 13 as a result of the generated magnetic field.

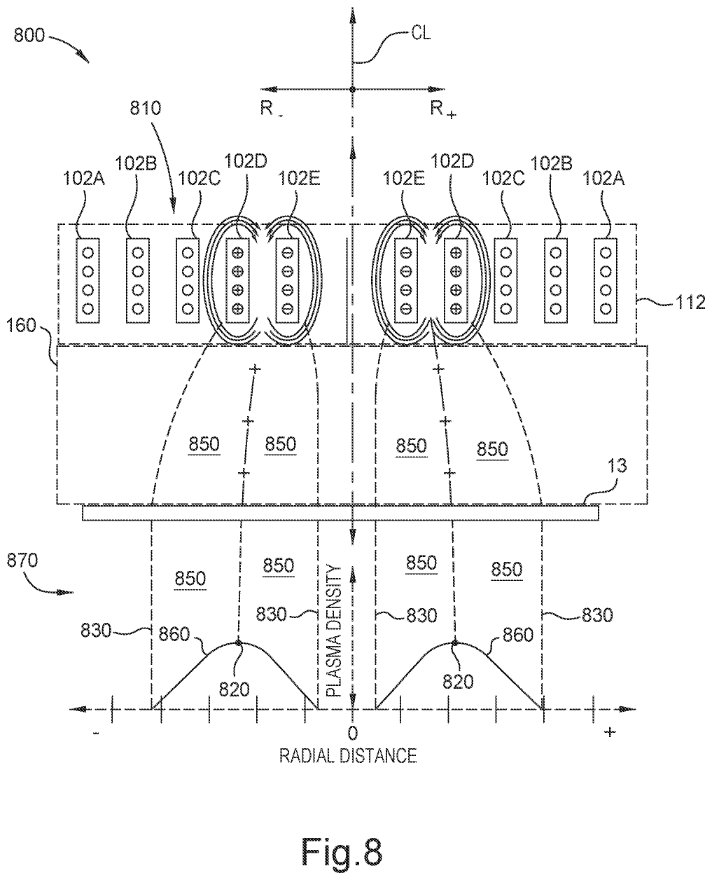

In another example illustrated in FIG. 8, fewer coils in the concentric coil region 112 are biased compared to the example of FIG. 6. For example, only two coils are biased (e.g., concentric coil 102D is biased in a positive direction and concentric coil 102E is biased in a negative direction). As a result, the radial length of the curve 760 (e.g., the width of the curve between the lines 730) is decreased, and therefore the position of the curve 760 will be changed as a result of the generated field lines 810 being more centric in the region of control 160, as illustrated in FIG. 8 as compared to the example of FIG. 6. As similarly discussed in relation to FIG. 6, the interactions between the coils biased in a positive direction and the coils biased in a negative direction generate a magnetic field with magnetic field lines 810 in the region of control 160 (above the substrate 13). The portion 870 of FIG. 8 depicts a graph with a curve 860 illustrating the plasma intensity in the region of control 850 (in the radial direction) across the substrate 13 formed as a result of the magnetic field generated by the concentric coil region 112. Lines 830 on the curve 860 represent the portion of the graph where the plasma intensity on the substrate 13 as a result of the formed null regions within the generated magnetic field, is at a minimum or is effectively zero. The point 820 on the curve 860 represents the peak or max plasma intensity on the substrate 13 as a result of the generated magnetic field. The intensity and shape of the curve 860 (the intensity and shape of the plasma density over the substrate 13) is dependent upon both the intensity of the magnetic field formed by the coils in the concentric coil region 112, which is affected by the state of the coils in the concentric coil region 112 (e.g., which coils are in the off position, being biased in a positive direction, and being biased in a negative direction).

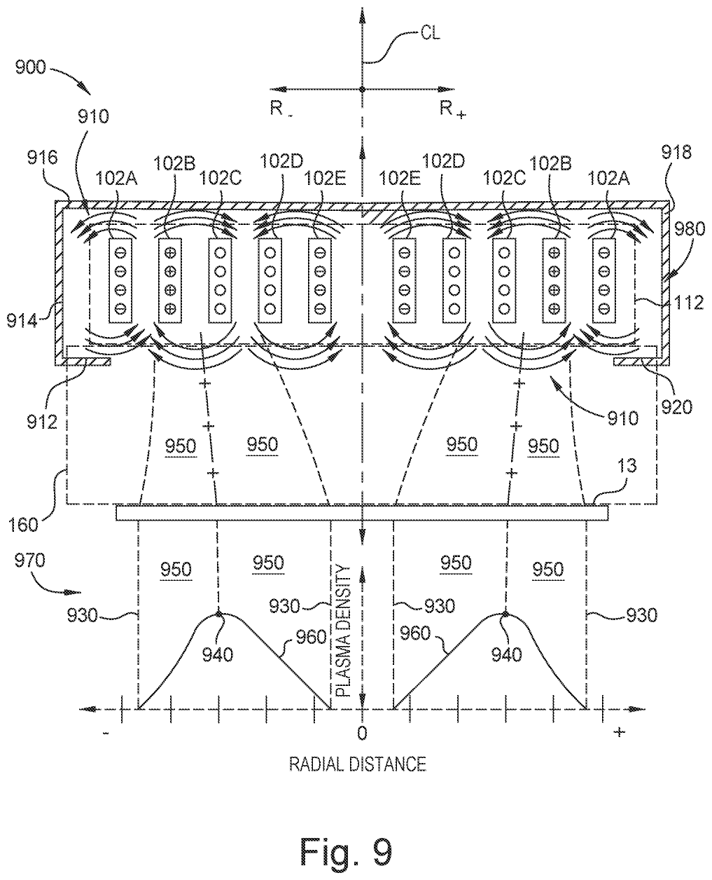

FIG. 9 illustrates the example in FIG. 6 with a shield barrier 980 within the concentric coil region 112, the shield barrier 980 being configured to block magnetic field lines from passing through regions of the plasma processing chamber. In some cases, the presence of the shield barrier 980 may further concentrate the generated magnetic field line (increasing the flux) in the region of control 160 by adding a return path. The presence of the shield barrier 980 may also reduce undesirable magnetic fields that may impact the area surrounding the plasma processing chamber 150. The shield barrier 980 may include a top portion 916, a left portion 914, and a right portion 918. In the example of FIG. 9, all of the field lines 910 corresponding to the generated magnetic field adjacent to the shield barrier 980 have been compressed (e.g., tight field lines 910), as a result of the blocking and shorting effect of the presence of the shield barrier 980 (with top portion 916, a left portion 914, and a right portion 918) over a similarly biased concentric coil region 112 shown in FIG. 6.

In some embodiments, the shield barrier 980 may also optionally include bottom portions 912, 920. As a result of optional portions 912, 920, the magnetic field is further affected, and the outside lines 930 representing where the plasma intensity over the substrate 13 are shifted towards the center of the substrate 13, which results in a decrease of the radial length of the curve 960 (e.g., the width of the curve between the lines 930) and a change in the position of the curve 960, as a result of the compression of the field lines 910 at the edges of the concentric coil region 112, as illustrated in FIG. 9 as compared to the example of FIG. 6.

In some embodiments, biasing the at least two of the plurality of concentric coils to adjust the generated magnetic field in the region of control 160 comprises biasing at least three of the plurality of concentric coils (e.g., three or more concentric coils 102A, 102B, 102C, 102D, 102E), as illustrated in FIGS. 6 and 7. In some embodiments, the power supply circuit may be configured to bias adjacent concentric coils so that the current flow through the coils is in opposite directions. In some embodiments, the region of control may have a peak radial field (e.g., represented by points 620, 720, 820, 940), and adjusting the generated magnetic field in the region of control 160 impacts the peak radial field, as described herein. In some embodiments, the power supply circuit may be configured to bias the at least two of the plurality of concentric coils (e.g., concentric coils 102A, 102B, 102C, 102D, 102E) in the concentric coil region 112 by driving the at least two of the plurality of concentric coils with a continuous direct current.

In some embodiments, the plurality of concentric coils comprise at least three adjacent concentric coils can be oppositely biased relative to each other to produce opposite fluxes when driven. In some embodiments, at least two of the plurality of concentric coils (e.g., concentric coils 102A, 102B, 102C, 102D, 102E) in the concentric coil region 112 may affect the plasma in the region of control 160 of the plasma processing chamber 150 through a metallic plate (e.g., showerhead 230) with a low magnetic permeability, as described above with respect to FIG. 1. Embodiments of the present disclosure allow for greater control of the plasma uniformity on the substrate 13 during plasma processing. In some embodiments, after the plasma 11 is formed within the processing volume 134 (e.g., activity 501), a power supply circuit may bias at least one of the concentric coils (e.g., concentric coils 102A, 102B, 102C, 102D, 102E) to affect the plasma density by changing an absolute magnitude of a current applied to the at least one concentric coil to change a radial flux in the region of control (e.g., activity 502). The characteristics of the plasma 11 may be optionally adjusted in an effort to adjust the plasma uniformity (e.g., plasma intensity, shape, and/or position) and plasma tilt in order to blur the inherent plasma non-uniformity created in one biased coil configuration versus another (e.g., activity 503), using, as an example, the method 500 illustrated in FIGS. 6-8.

In one example, at a first time T1, three concentric coils may be biased in a manner similar to FIG. 6, where concentric coils 102C and 102D are in an “off position,” concentric coil 102B are biased in a positive direction, and concentric coils 102A and 102E are biased in an opposing negative direction. At a second time T2, the bias, and thus the current flow through one or more of the coil regions, such as radial coils 102H and 1021 are increased (e.g., FIG. 7). Then, at a third time T3, the concentric coils may be biased in a manner similar to FIG. 8, where concentric coils 102A, 102B, and 102C are in an “off position,” concentric coil 102D is biased in a positive direction, and concentric coil 102E is biased in a negative direction. The adjustment of the current flow provided to one or more of the concentric coils during each of the three times T1, T2 and T3 causes the plasma characteristics during each of these times to be altered such that alterations in the plasma created during different parts of a plasma processing recipe performed on a substrate or inherent variation in the processing chamber environment (e.g., center to edge plasma non-uniformity) can be accounted for, controlled and minimized. Therefore, by use of the controller 126 and software programs stored in memory 128, the current flowing through each of the concentric coils 102A, 102B, 102C, 102D, 102E at different times during a plasma process being performed on a substrate can be adjusted as desired to blur the inherent plasma non-uniformity created in one biased coil configuration versus another.

### ADDITIONAL CONSIDERATIONS

The term “coupled” is used herein to refer to the direct or indirect coupling between two objects. For example, if object A physically touches object B and object B touches object C, then objects A and C may still be considered coupled to one another-even if objects A and C do not directly physically touch each other. For instance, a first object may be coupled to a second object even though the first object is never directly physically in contact with the second object.

While the foregoing is directed to embodiments of the present disclosure, other and further embodiments of the disclosure may be devised without departing from the basic scope thereof, and the scope thereof is determined by the claims that follow.

What is claimed is:

1. A plasma processing chamber, comprising:
a concentric coil region comprising a first concentric coil, a second concentric coil, and a third concentric coil, wherein
the first concentric coil comprises a first coil that has a first radius that is measured in a direction parallel to a first plane,
the second concentric coil comprises a second coil that has a second radius that is measured in a direction parallel to the first plane,
the third concentric coil comprises a third coil that has a third radius that is measured in a direction parallel to the first plane,
the second radius is smaller than the third radius, and the first radius is smaller than the second radius; and
a power supply circuit coupled to the first concentric coil, the second concentric coil, and the third concentric coil, wherein the power supply circuit is configured to bias the first concentric coil, the second concentric coil, and the third concentric coil to adjust a generated magnetic field in a region of control of a plasma in the plasma processing chamber to control a plasma density of the plasma, and wherein at least one of the first concentric coil, the second concentric coil, and the third concentric coil is biased oppositely of the other concentric coils.

2. The plasma processing chamber of claim 1, wherein the power supply circuit is configured to bias the first concentric coil, the second concentric coil, and the third concentric coil to affect the plasma density by changing an absolute magnitude of a current applied to the first concentric coil and the second concentric coil to change a radial flux in the region of control.

3. The plasma processing chamber of claim 1, wherein:
the power supply circuit is further configured to bias adjacent concentric coils in opposite directions.

4. The plasma processing chamber of claim 1, wherein:
the region of control has a peak radial field; and
when the generated magnetic field in the region of control of the plasma in the plasma processing chamber is adjusted, the peak radial field is also adjusted.

5. The plasma processing chamber of claim 1, wherein:
each of the first concentric coil, the second concentric coil, and the third concentric coil comprise multiple coil layers.

6. The plasma processing chamber of claim 1, wherein:
the power supply circuit is configured to bias at least one of the first concentric coil, the second concentric coil, and the third concentric coil by driving the first concentric coil, the second concentric coil, and the third concentric coil with a continuous direct current.

7. The plasma processing chamber of claim 1, wherein:
the first concentric coil, the second concentric coil, and the third concentric coil adjust the generated magnetic field in the region of control of the plasma in the plasma processing chamber to control the plasma density of the plasma in the plasma processing chamber through a metallic plate with a high magnetic permeability.

8. The plasma processing chamber of claim 1, wherein:
the first concentric coil, the second concentric coil, and the third concentric coil are substantially surrounded by a shield barrier on at least one side; and
the shield barrier is configured to substantially block the generated magnetic field.

9. The plasma processing chamber of claim 8, wherein:
the shield barrier is configured to substantially block the generated magnetic field.

10. The plasma processing chamber of claim 1, wherein:
the concentric coil region comprises an even number of concentric coils; and
adjacent concentric coils are wound oppositely to produce opposite fluxes when driven.

11. A method of processing a substrate, comprising performing a processing sequence on the substrate disposed within a processing region of a plasma processing chamber, wherein the processing sequence comprises:
biasing, with a power supply circuit, at least three of a plurality of concentric coils to adjust a generated magnetic field in a region of control of a plasma in the plasma processing chamber to control a plasma density of the plasma by changing an absolute magnitude of a current applied to the at least three of the plurality of concentric coils to change a radial flux in the region of control, wherein the biasing the at least three of the plurality of concentric coils comprises:
delivering a first bias signal to a coil of a first concentric coil of the plurality of concentric coils;
delivering a second bias signal to a coil of a second concentric coil of the plurality of concentric coils; and
delivering a third bias signal to a coil of a third concentric coil of the plurality of concentric coils, and wherein at least one of the at least three of the plurality of concentric coils is biased oppositely of the other concentric coils.

12. The method of claim 11, wherein:
the power supply circuit is further configured to bias adjacent concentric coils in opposite directions.

13. The method of claim 11, wherein:
the region of control has a peak radial field; and
when the generated magnetic field in the region of control of a plasma in the plasma processing chamber is adjusted, the peak radial field is also adjusted.

14. The method of claim 11, wherein:
each of the plurality of concentric coils comprise multiple coil layers.

15. The method of claim 11, wherein:
the power supply circuit is configured to bias the plurality of concentric coils by driving the plurality of concentric coils with a continuous direct current.

16. The method of claim 11, wherein:
the plurality of concentric coils affect the plasma in the plasma processing chamber through a metallic plate with a high magnetic permeability.

17. The method of claim 11, wherein:
plurality of concentric coils are substantially surrounded by a shield barrier on at least one side.

18. The method of claim 17, wherein:
the shield barrier is configured to substantially block the generated magnetic field.

19. The method of claim 11, wherein:
the plurality of concentric coils comprise an even number of coils; and
adjacent concentric coils are wound oppositely to produce opposite fluxes when driven.

20. A method of processing a substrate, comprising performing a processing sequence on the substrate disposed within a processing region of a plasma processing chamber, wherein the processing sequence comprises:
biasing, with a power supply circuit, at least two of a plurality of concentrically aligned coils to adjust a generated magnetic field in a region of control of a plasma in the plasma processing chamber to control a plasma density of the plasma by changing an absolute magnitude of a current applied to the at least two of the plurality of concentrically aligned coils to change a radial flux in the region of control, wherein the biasing the at least two of the plurality of concentrically aligned coils comprises:
delivering a first bias signal to a coil of a first concentric coil of the plurality of concentrically aligned coils at a first time; and
delivering a second bias signal to a coil of a second concentric coil of the plurality of concentrically aligned coils at a second time.
